(19) United States
(12) Patent Application Publication
(10) Pub. No.: US 2026/0197015 A1
(43) Pub. Date: Jul. 9, 2026

(54) Linear Digital-to-Analog Converters with Constant Current Consumption

(71) Applicant: Apple Inc., Cupertino, CA (US)

(72) Inventor: Antonio Passamani, Munich (DE)

(21) Appl. No.: 19/014,551

(22) Filed: Jan. 9, 2025

(51) Int. Cl. H04B 1/00; H03K 19/20

(52) U.S. Cl. CPC H04B 1/0014; H03K 19/20

(57) ABSTRACT

An electronic device may include wireless circuitry. The wireless circuitry may include a radio-frequency transmit path with a radio-frequency digital-to-analog converter (RFDAC). The RFDAC may include a digital-to-analog converter (DAC) circuit and a corresponding replica circuit. The RFDAC may receive a digital code that programs an amount of current consumption by the DAC circuit to meet requirements associated with transmission of the radio-frequency signal. The RFDAC may process the digital code and may use a portion of the digital code to control the replica circuit to produce an inverse replica of the current consumed by the DAC circuit, which may be shunted to ground. This may achieve a constant current consumption by the RFDAC that allows for increased linearity of the RFDAC.

### FIELD

This disclosure relates generally to electronic devices, including electronic devices with wireless communications circuitry.

### BACKGROUND

Electronic devices can be provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals transmitted by an antenna can be fed through a radio-frequency digital-to-analog converter that performs both signal domain conversion and frequency upconversion. It can be challenging to provide radio-frequency digital-to-analog converters with sufficient levels of performance.

### SUMMARY

An electronic device may include wireless circuitry. The wireless circuitry may include a radio-frequency transmit path. The transmit path may include processing circuitry, a radio-frequency digital-to-analog converter (RFDAC), an amplifier, and an antenna. The transmit path may transmit a baseband signal. The RFDAC may generate a radio-frequency signal based on the baseband signal. The amplifier may amplify the radio-frequency signal. The antenna may radiate the radio-frequency signal.

The RFDAC may include a digital-to-analog converter (DAC) circuit and a corresponding replica circuit (e.g., in a set of one or more cells). The RFDAC may receive a digital code that programs an amount of current consumption by the DAC circuit to meet requirements associated with transmission of the radio-frequency signal. The RFDAC may process the digital code and may use a portion of the digital code to control the replica circuit to produce an inverse replica of the current consumed by the DAC circuit, which may be shunted to ground. This may achieve a constant current consumption by the RFDAC that allows for increased linearity of the RFDAC. The RFDAC may operate on in-phase and quadrature-phase signals if desired. The DAC circuit may be a control DAC (CDAC) circuit or another type of DAC circuit.

An aspect of the disclosure provides a radio-frequency digital-to-analog converter (RFDAC). The RFDAC can include a signal path that includes a first logic AND gate and a first capacitor coupled in series between an output of the first logic AND gate and a radio-frequency output of the RFDAC. The RFDAC can include a replica path coupled between first and second inputs of the first logic AND gate and a ground potential. The replica path can include a second logic AND gate. The replica path can include a second capacitor coupled in series between an output of the second logic AND gate and the ground potential.

An aspect of the disclosure provides a radio-frequency digital-to-analog converter (RFDAC). The RFDAC can include a first logic OR gate. The RFDAC can include a first capacitor coupled between an output of the first logic OR gate and a ground potential. The RFDAC can include a second logic OR gate. The RFDAC can include a second capacitor coupled between an output of the second logic OR gate and a radio-frequency output of the RFDAC. The RFDAC can include a first logic AND gate having an output coupled to a first input of the second logic OR gate. The RFDAC can include a second logic AND gate coupled between first and second inputs of the first logic AND gate and a first input of the first logic OR gate.

An aspect of the disclosure provides wireless circuitry. The wireless circuitry can include a digital-to-analog converter circuit (DAC) configured to consume a current, wherein the DAC circuit has a first control input configured to receive, from a control path, a digital code that sets an amount of the current consumed by the DAC circuit. The wireless circuitry can include a replica circuit configured to consume an inverse replica of the current, wherein the replica circuit has a second control input configured to receive a digital control signal that sets an amount of the inverse replica of the current consumed by the replica circuit, the digital control signal comprising some but not all of the digital code.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having radio-frequency amplifiers in accordance with some embodiments.

FIG. 3 is a diagram of illustrative transmit circuitry that includes a radio-frequency digital-to-analog converter (RFDAC) in accordance with some embodiments.

FIGS. 4 and 5 are diagrams of an illustrative RFDAC that includes a digital-to-analog converter (DAC) circuit and a corresponding replica circuit in accordance with some embodiments.

FIG. 6 is a circuit diagram of an illustrative RFDAC cell that includes a primary path and a replica path in accordance with some embodiments.

FIG. 7 is a circuit diagram of an illustrative RFDAC that includes a set of cells in accordance with some embodiments.

FIG. 8 is a circuit diagram of an illustrative RFDAC having replica paths that are separated from primary paths of the RFDAC in accordance with some embodiments.

FIG. 9 is a diagram of an illustrative RFDAC that includes multiple rows and columns of cells in accordance with some embodiments.

FIG. 10 is a diagram of an illustrative controller for replica paths of an RFDAC in accordance with some embodiments.

FIG. 11 is a schematic diagram of an illustrative RFDAC that operates on in-phase and quadrature-phase (i/q) signals in accordance with some embodiments.

FIG. 12 is a circuit diagram of an illustrative RFDAC that operates on i/q signals in accordance with some embodiments.

FIG. 13 is a plot of current as a function of time for an illustrative RFDAC under different operating conditions in accordance with some embodiments.

FIG. 14 is a flow chart of illustrative operations involved in transmitting radio-frequency signals using an RFDAC of the types shown in FIGS. 3-13 in accordance with some embodiments.

### DETAILED DESCRIPTION

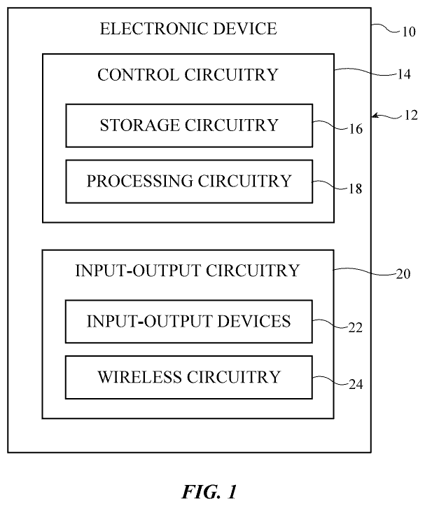

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses, goggles, a helmet, or other equipment worn on a user's head (e.g., an augmented, virtual, or mixed reality head-mounted display device), or another wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more processors such as microprocessors, microcontrollers, digital signal processors, host processors, baseband processor integrated circuits, application specific integrated circuits, central processing units (CPUs), graphics processing units (GPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 3GPP Fifth Generation (5G) New Radio (NR) protocols, Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), antenna-based spatial ranging protocols, optical communications protocols, or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), a Wi-Fi® 7 band, and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1(FR 1 ) bands below 10 GHz, 5G New Radio Frequency Range 2(FR 2 ) bands between 20 and 60 GHz, etc.), other centimeter or millimeter wave frequency bands between 10-100 GHz, sub-THz frequency bands between around 100 GHz and 10 THz (e.g., 6G bands), near-field communications (NFC) frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, satellite communications (satcom) bands, unlicensed bands, communications bands under the family of 3GPP wireless communications standards, communications bands under the IEEE 802.XX family of standards, and/or any other desired frequency bands of interest.

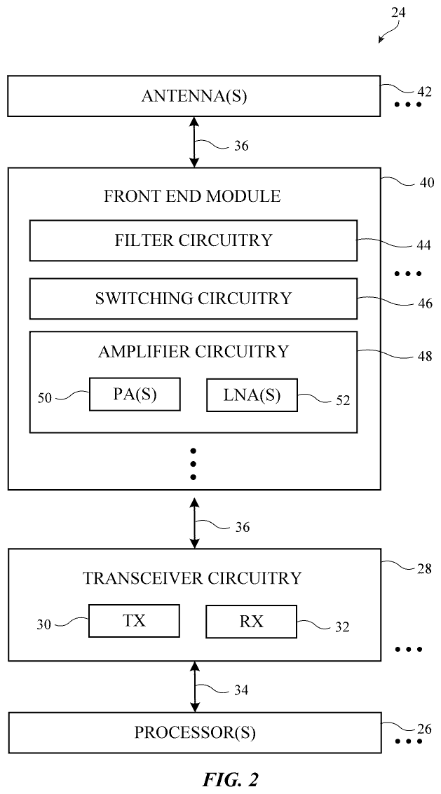

FIG. 2 is a diagram showing illustrative components within wireless circuitry 24. As shown in FIG. 2, wireless circuitry 24 may include a processor such as processor 26, radio-frequency (RF) transceiver circuitry such as radio-frequency transceiver 28, radio-frequency front end circuitry such as radio-frequency front end module (FEM) 40, and antenna(s) 42. Processor 26 may be a baseband processor, application processor, general purpose processor, microprocessor, microcontroller, digital signal processor, host processor, application specific signal processing hardware, or other type of processor. Processor 26 may be coupled to transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 28, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processor 26 may provide transmit signals (e.g., digital or baseband signals) to transceiver 28 over path 34. Transceiver 28 may further include circuitry for converting the transmit (baseband) signals received from processor 26. For example, transceiver circuitry 28 may include mixer circuitry for up-converting (or modulating) the transmit (baseband) signals to radio frequencies prior to transmission over antenna 42. The example of FIG. 2 in which processor 26 communicates with transceiver 28 is merely illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front end module 40. Transceiver 28 may include circuitry such as receiver (RX) 32 for receiving signals from front end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processor 26 over path 34.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifiers 50 and/or one or more low-noise amplifier circuits 52), signal attenuators, impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1(FR 1 ) bands below 10 GHz, 5G New Radio Frequency Range 2(FR 2 ) bands between 20 and 60 GHz, 6G bands above 100 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

As described above, front end module 40 may include one or more power amplifiers (PAs) 50 in the transmit (uplink) path. A power amplifier 50 (sometimes referred to as a radio-frequency power amplifier, transmit amplifier, or amplifier) may be configured to amplify a radio-frequency signal without changing the signal shape, format, or modulation. Amplifier 50 may, for example, be used to provide 10 dB of gain, 20 dB of gain, 10-20 dB of gain, less than 20 dB of gain, more than 20 dB of gain, or other suitable amounts of gain.

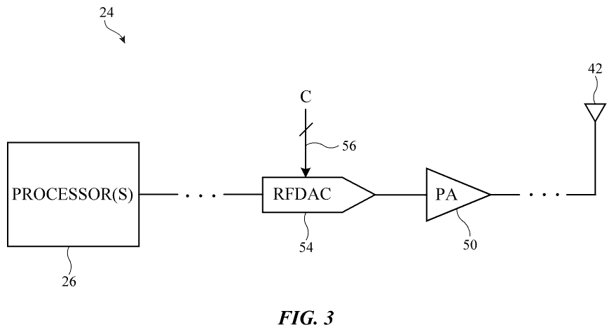

FIG. 3 is a diagram of an illustrative transmit path of wireless circuitry 24. As shown in FIG. 3, wireless circuitry 24 may include processing circuitry such as one or more processors 26, a radio-frequency converter block such as radio-frequency converter block 54, radio-frequency amplifier circuitry such as radio-frequency amplifier 50 (e.g., a power amplifier), and an antenna 42 configured to radiate radio-frequency signals output by amplifier 50. Amplifier 50 may be disposed on FEM 40 or in transceiver circuitry 28 of FIG. 2. Processor(s) 26 may represent one or more processors such as a baseband processor, an application processor, a digital signal processor, a microcontroller, a microprocessor, a central processing unit (CPU), a programmable device, a combination of these circuits, and/or one or more processors within circuitry 18 of FIG. 1. Processor(s) 26 may be configured to generate a digital baseband signal. The baseband signal is sometimes referred to as a digital signal or a transmit signal. As examples, the baseband signal generated by processor(s) 26 may include in-phase and quadrature-phase signals, radius and phase signals, a vector input, or other digitally coded signals.

Radio-frequency converter block 54 may be configured to convert the digital baseband signal from the digital domain to the analog domain and to upconvert (modulate) the analog signals to radio frequencies. The term “radio-frequency converter” may thus refer to and be defined herein as a circuit that can perform both signal domain conversion (e.g., digital to analog conversion) and frequency upconversion (e.g., from baseband frequencies to radio frequencies or intermediate frequencies). The input of amplifier 50 configured to receive radio-frequency signals can be referred to or defined herein as a radio-frequency input (port). Radio frequencies can range from a few kHz to tens of THz. Radio-frequency converter block 54 may output a radio-frequency signal to the radio-frequency input of amplifier 50. Amplifier 50 may generate a corresponding amplified radio-frequency signal that can then be radiated by antenna(s) 42.

The example described above in which converter block 54 performs digital-to-analog conversion before conducting frequency upconversion in the analog domain is illustrative. In another embodiment, RF converter block 54 can perform frequency upconversion in the digital domain before conducting digital-to-analog conversion. In general, RF converter block 54 may include a set of N individual digital-to-analog converter (DAC) circuits or DACs, each of which is sometimes referred to or defined herein as a radio-frequency digital-to-analog converter (RFDAC) cell (e.g., converter block 54 can include N separate RFDAC cells). For example, N can be any integer greater than or equal to one, two, four, four to ten, greater than 10, 10 to 20, greater than 20, or another integer value. RF converter block 54 is sometimes also referred to herein as RFDAC circuitry 54 or RFDAC 54. RFDAC 54 may contain a set of one or more individual RFDAC cells. An RFDAC cell is sometimes also referred to on its own as an RFDAC Tile or simply as an RFDAC.

RFDAC 54 may be a programmable RFDAC that has a digital control input coupled to digital control path 56. RFDAC 54 may receive a control signal such as digital code C at its control input over digital control path 56. Processor(s) 26 or other processing circuitry in processing circuitry 18 (FIG. 1) may generate digital code C to control the operation of RFDAC 54. During signal transmission, RFDAC 54 may receive digital data from processor(s) 26 (e.g., baseband data). RFDAC 54 may convert the digital data from the digital domain to the analog domain (e.g., as an analog signal) and may also upconvert the analog signal to a radio frequency. RFDAC 54 may transmit an analog radio-frequency signal to amplifier 50, which amplifies the radio-frequency signal for transmission over antenna 42. Digital code C may, for example, set the amount of current consumed by RFDAC 54 while converting and transmitting signals (e.g., by controlling the number of cells in the RFDAC that are active at a given time). Digital code C may, for example, exhibit a range of possible digital values (codes) from a minimum digital code associated with a minimum amount of current consumption by RFDAC 54 (e.g., a minimum number of active cells or no active RFDAC cells) to a maximum digital code associated with a maximum amount of current consumption by RFDAC 54 (e.g., a maximum number of active RFDAC cells). The minimum digital code may, for example, be associated with no current consumption by RFDAC 54 (e.g., RFDAC 54 may be turned off, disabled, or inactive while programmed/configured using its minimum digital code and may be turned, enabled, or active while programmed/configured using other digital codes).

In some implementations, which are sometimes described herein as an example, RFDAC 54 may include one or more control DACs (CDACs or C-DACs) (e.g., implemented in a set of CDAC cells that are selectively activated or deactivated depending on the state of digital code C). A CDAC may include a class-D output stage, which can provide the RFDAC with relatively high efficiency and output power. A class-D output stage consumes an amount of current that scales with the amplitude of the desired radio-frequency signal to be output from the RFDAC, whereas a class-A output stage always consumes a large amount of current regardless of the amplitude of the desired radio-frequency signal to be output from the RFDAC. Put differently, the class-D output stage of a CDAC may configure the CDAC to exhibit relatively high efficiency by scaling current consumption based on how much power is actually demanded by the output load of the RFDAC. For example, for transmit signals with a high peak-to-average power ratio (PAPR) (e.g., 256-QAM modulated signals) where PAPR can be as high as 12 dB, assuming identical efficiency between class-A and class-D output stages at maximum code, a class-A output stage may need to constantly consume a relatively high current, such as 100 mA, whereas a class-D output stage may only need to occasionally consume such a high level of current, with an average consumption that is much lower than 100 mA.

However, under some circumstances, large variation in current consumption by the class-D output stage may create a performance bottleneck. In addition, class-D output stages tend to exhibit no intrinsic power-supply-rejection ratio (PSRR) because its load is connected directly to a rail or ground voltage and can require a robust power supply system. The power supply system may, for example, require strong local regulation (e.g., for providing a steady power supply over time), as a large current swing can result in a large voltage drop on a given power supply. Such a strong local regulation system may need to exhibit sufficient speed to react to rapid transmit signal changes and may need to exhibit a relatively large bandwidth. In some situations, large capacitances are used to regulate high frequency spikes in current consumption. These large capacitances, as well as strict requirements on routing, may cause the RFDAC to consume an excessive amount of chip area in wireless circuitry 24 and may require significant current consumption in the local loop regulation (e.g., in addition to 20-30% voltage drop lost on the pass device).

In some implementations, the power supply system for the RFDAC is provided with a shunt regulator that constantly consumes an amount of current proportional to the maximum required current minus the instantaneously required current of the RFDAC. This type of shunt regulator may need to be relatively large and fast. However, because the origin of current scaling versus code for RFDACs may be predictable against the applied code due mainly to the change in internal loading of the DAC amongst its parasitic nodes before output current is produced, other approaches may be possible. Although implementations in which RFDAC 54 includes a radio-frequency CDAC are sometimes described herein as an example, RFDAC 54 may in general include any desired RFDAC circuitry that exhibits significant changes in current consumption during operation at different code levels (e.g., while programmed/configured using different values of digital code C).

To help mitigate these issues and to optimize the performance of RFDAC 54 and wireless circuitry 24, RFDAC 54 may include a DAC circuit and a corresponding replica circuit. The replica circuit may consume an inverse of the current consumed by the DAC circuit (sometimes also referred to herein as an inverse replica current or an inverse compensation current) over time. This may help to ensure that the DAC circuit and the corresponding replica circuit collectively consume constant current over time. This may configure RFDAC 54 to exhibit greater linearity than in the absence of the replica circuit, at the expense of higher overall current consumption.

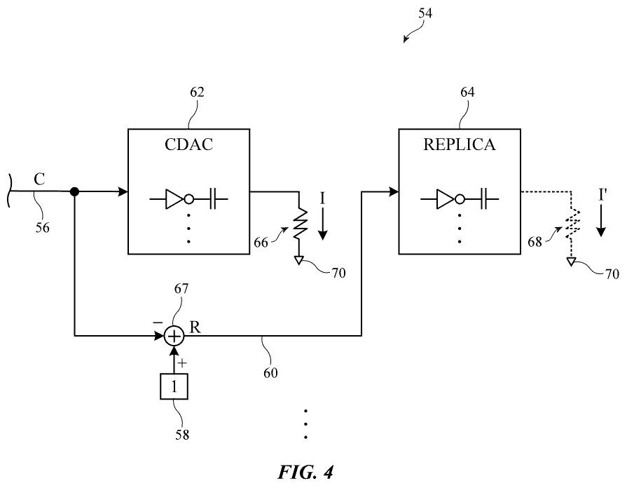

FIG. 4 is a diagram showing one example of how RFDAC 54 may include a DAC circuit 62 and a corresponding replica circuit 64 (e.g., in a given cell of RFDAC 54). DAC circuit 62 may be, for example, a CDAC or another type of DAC. Replica circuit 64 may be a replica of DAC circuit 62 (e.g., may contain some or all of the same circuitry as DAC circuit 62) or may include different circuitry than DAC circuit 62. Replica circuit 64 is sometimes also referred to herein as replica DAC 64 (e.g., a replica CDAC), compensation circuit 64, replica current generator 64, inverse replica current generator 64, or compensation current generator 64. DAC circuit 62 may include one or more primary DAC paths (e.g., containing digital driving logic and one or more capacitors used in performing signal conversion). Replica circuit 64 may include one or more replica paths (e.g., containing digital driving logic and one or more capacitors used in generating inverse replica current).

As shown in FIG. 4, DAC circuit 62 may have a digital control input coupled to digital control path 56. DAC circuit 62 may receive digital code C over digital control path 56. RFDAC 54 may also include an arithmetic circuit 67 (e.g., an adder or subtractor). Arithmetic circuit 67 may have a first (e.g., negative) input coupled to digital control path 56. Arithmetic circuit 67 may have a second (e.g., positive) input that receives a digital constant such as constant 58 (e.g., a constant voltage level or offset). Arithmetic circuit 67 has an output coupled to a digital control input of replica circuit 64 over digital control path 60. Arithmetic circuit 67 may perform a digital arithmetic operation on digital signals received at its first and second inputs to produce a digital control signal R (e.g., another digital code) on control path 60. Digital control signal R may control the operation of replica circuit 64 (e.g., similar to the control of DAC circuit 62 by digital code C).

Arithmetic circuit 67 may generate digital control signal R by subtracting the digital signal received at its first input from the constant 58 received at its second input (or equivalently by adding an inverse of the digital signal received at its first input to the digital signal received at its second input). In the example of FIG. 4, for instance, the digital codes of RFDAC 54 are normalized to one and arithmetic circuit 67 generates digital control signal R by subtracting digital code C from a constant 58 that is equal to one (e.g., where R=1−C, or equivalently R+C=1). This is illustrative and non-limiting and, in general, constant 58 may be any desired value. Constant 58 is sometimes also referred to herein as digital offset 58, offset voltage 58, or offset 58.

DAC circuit 62 may have a signal output terminal (e.g., a radio-frequency output terminal or port) coupled to output load 66, modeled as a resistor coupled to ground 70 (or another reference potential) in FIG. 4 for the sake of simplicity. Output load 66 may, for example, include some or all of amplifier 50 (FIG. 3). If desired, replica circuit 64 may also have an output terminal or port coupled to ground 70 (or another reference potential) through replica load 68. Replica load 68 may form a shunt path to ground for current produced by replica circuit 64.

During signal transmission, digital code C may configure or program DAC circuit 62 to consume a particular magnitude of current I (e.g., passing through or to output load 66). For example, digital code C may control the number of active DAC circuits 62 (e.g., CDAC cells) that are active or turned on during signal transmission in the RFDAC. Changing digital code C over time may change the magnitude of current I over time as needed given the operating conditions of wireless circuitry 24. At the same time, arithmetic circuit 67 may generate digital control signal R based on constant 58 and digital code C (e.g., digital control signal R may represent some but not all of digital code C). Digital control signal R (e.g., some but not all of digital code C) may configure or program replica circuit 64 to consume a corresponding current I′ (e.g., passing through replica load 68). Current I′ may be an inverse replica of the current I consumed by DAC circuit 62 (e.g., where current I′ has a current waveform over time that is inverted relative to the current I consumed by DAC circuit 62). For example, digital control signal R may control the number of active replica circuits (cells) 64 that are active or turned on during signal transmission in the RFDAC.

Whenever digital code C is changed (e.g., by the control circuitry supplying digital code C) to adjust the current I consumed by DAC circuit 62 (e.g., a number A of active CDAC cells or DAC circuits 62 in the RFDAC), digital control signal R is updated by arithmetic circuit 67 to change digital control signal R in a manner that causes a corresponding adjustment to the current I′ consumed by replica circuit 64 (e.g., a number D of active replica circuits 64 in the RFDAC). For example, increasing digital code C may increase the number A of active DAC circuits 62 (e.g., CDAC cells) that are coupled into the signal path and thus activated during signal transmission. At the same time, the corresponding digital control signal R may control the RFDAC such that increasing digital code C decreases the number D of active replica circuits forming shunt paths between the signal path and ground (e.g., the number D of active replica circuits 64 shunting the signal path to ground may be inversely proportional to digital code C, whereas the number A of active CDAC cells coupled into the signal path may be directly proportional to digital code C). The production of current I′ may, for example, cause RFDAC 54 to consume a constant amount of current (e.g., given by the sum of the current I consumed by DAC circuit 62 and the current I′ consumed by replica circuit 64) over time, which may allow RFDAC 54 to exhibit higher linearity than in implementations without replica circuit 64. Current I′ is sometimes also referred to herein as replica current I′, inverse replica current I′ (e.g., an inverse replica of current I), shunt current I′, inverse replica shunt current I′, or compensation current I′ (e.g., compensating for the current I consumed by DAC 62).

If desired, replica load 68 may be omitted (e.g., replica circuit 64 need not be shunted to ground). Alternatively, if desired, RFDAC 54 may include switching circuitry (e.g., one or more switches) that selectively couples replica circuit 64 to replica load 68 and/or ground 70 and/or that selectively switches replica load 68 into or out of use between replica circuit 64 and ground 70. For example, the replica load may be omitted or may be switched out of use when DAC circuit 62 is operating in a low efficiency region or mode (e.g., when only a minority of the current consumed flows to output load 66).

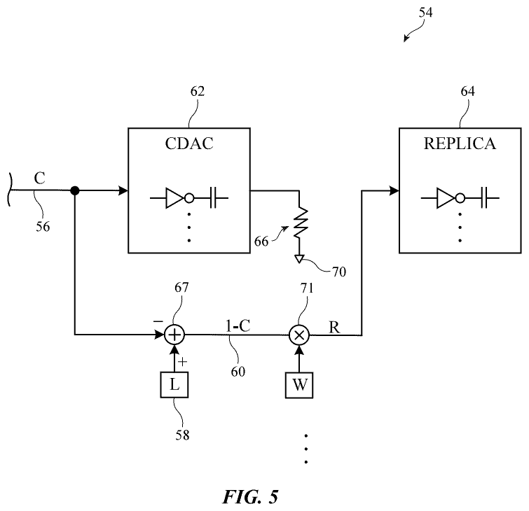

The example of FIG. 4 is illustrative and non-limiting. If desired, arithmetic circuit 67 may be integrated into replica circuit 64 (e.g., may form a part of replica circuit 64). If desired, partialisation may be achieved by applying a weight to the digital control signal used to program replica circuit 64. FIG. 5 is a circuit diagram showing one example in which RFDAC 54 implements a partialisation scheme. In the example of FIG. 5, replica load 68 has been omitted. If desired, replica circuit 64 of FIG. 5 may be provided with a replica load 68 (FIG. 4).

As shown in FIG. 5, RFDAC 54 may include digital multiplier circuitry such as multiplier 71 (sometimes also referred to herein as weighting circuitry 71). Multiplier 71 may have a first input coupled to digital control path 60. Multiplier 71 may have a second input that receives a weight value W (e.g., a digital voltage level or offset). Multiplier 71 may have an output coupled to the digital control input of replica circuit 64. In this example, arithmetic circuit 67 may provide a digital signal at a level of (L−C) to the first input of multiplier 71 (e.g., where constant 58 is equal to a limit value L). Multiplier 71 may generate the digital control signal R used to program replica circuit 64 by multiplying the digital signal received over digital control path 60 by weight value W (e.g., where R=W*(L−C)). In this way, weight value W may be used to effectively weight the digital code used to control current consumption in replica circuit 64.

Weight values W may be applied to the total number of DAC cells corrected and/or the gain of correction. As one example, weight values W may be used to limit the maximum number of correction cells in RFDAC 54 (e.g., where R=max(0.5−W*C, 0)). However, because of the limit function introduced by the function max(), the current consumption of the sum of the global partial replica circuits and the DAC circuits across cells in RFDAC 54 could result in a higher frequency profile than the original current profile of the DAC circuit, albeit at a reduced maximum swing. This may be overcome using gain weighting (e.g., setting R=0.5*(1−C)). This may serve to mitigate current peaks without introducing higher frequency components in the power supply. When it is known that the maximum power will not exceed limit L (e.g., when a backed-off output power level is selected for transmission rather than a maximum output power level, when the transceiver is closer to the antenna, etc.), then the maximum number of activated replica cells across RFDAC 54 may be limited to limit L to save power consumption (e.g., where R=L−C and L is less than 1). For example, when C is limited to be smaller than L=0.5, or 25% output power assuming C is linear in voltage, R may be given by R=0.5−C. Note that there is no max() function required in this case, since R cannot accept negative numbers due to C being limited to L=0.5. This example is illustrative and non-limiting. If desired, arithmetic circuit 67 and/or multiplier 71 may be integrated into replica circuit 64.

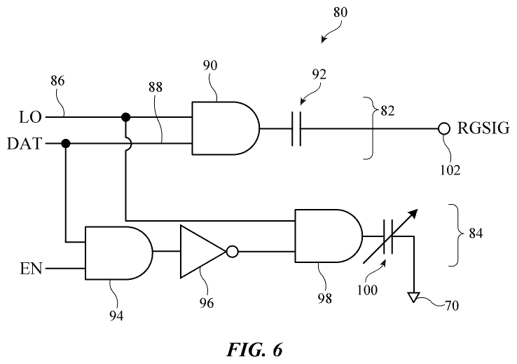

FIG. 6 is a circuit diagram showing one example of an illustrative cell 80 of RFDAC 54. In general, RFDAC 54 may include a set of N cells 80, one of which is illustrated in FIG. 6. As shown in FIG. 6, cell 80 may include a primary path 82 (sometimes also referred to herein as signal path 82, primary circuitry 82, main path 82, primary DAC path 82, or main DAC path 82) and a corresponding replica path 84 (sometimes also referred to herein as replica circuitry 84, compensation path 84, correction path 84, or shunt path 84). Primary path 82 may form some or all of a DAC circuit 62 in RFDAC 54 (FIGS. 4 and 5). Replica path 84 may form some or all of a replica circuit 64 in RFDAC 54 (FIGS. 4 and 5). In the example of FIG. 6, primary path 82 implements a CDAC circuit in cell 80. This is illustrative and non-limiting.

Primary path 82 may include a logic gate such as logic AND gate 90 coupled in series with output capacitor 92 (e.g., logic AND gate 90 may form a driver that drives output capacitor 92). Logic AND gate 90 may have a first signal input coupled to clocking path (line) 86 and may have a second signal input coupled to data path (line) 88. Logic AND gate 90 may have an output communicatively coupled to a radio-frequency signal output terminal (port) of cell 80 and/or RFDAC 54 such as output terminal 102. Output capacitor 92 may be coupled in series between the output of logic AND gate 90 and output terminal 102. Logic AND gate 90 may receive an oscillating signal such as local oscillator signal LO from clocking circuitry over clocking path 86. Logic AND gate 90 may receive a stream of digital data (e.g., baseband data) such as data DAT over data path 88 (e.g., from processor(s) 26 of FIG. 3). Output terminal 102 may be operably coupled to output load 66 (FIGS. 4 and 5).

Replica path 84 may include a first digital logic gate such as logic AND gate 94, an inverting circuit such as inverter 96 (e.g., a digital logic NOT gate), and a second digital logic gate such as logic AND gate 98, coupled in series with a replica capacitor such as capacitor 100 (e.g., logic AND gate 94 may drive inverter 96, which drives logic AND gate 98, which drives replica capacitor 100). Logic AND gate 94 may have a first signal input coupled to clocking path 86. Logic AND gate 94 may receive local oscillator signal LO at its first signal input from clocking path 86. Logic AND gate may have a second signal input that receives a digital enable signal such as enable signal EN (e.g., from a replica controller in processor(s) 26 of FIG. 3, control circuitry 14 of FIG. 1, etc.). Logic AND gate 94 may have an output coupled to the input of inverter 96. Enable signal EN may represent or include some or all of the digital code C provided to RFDAC 54 (FIGS. 4 and 5) and/or the digital control signal R provided to replica circuit 64 (FIGS. 4 and 5).

Logic AND gate 98 may have a first signal input coupled to clocking path 86. Logic AND gate 98 may receive local oscillator signal LO at its first signal input from clocking path 86. Logic AND gate 98 may have a second signal input coupled to the output of inverter 96. Logic AND gate 98 may have an output coupled to ground 70. Replica capacitor 100 may be coupled in series between the output of logic AND gate 98 and ground 70 (e.g., replica capacitor 100 may form a current shunt path to ground 70 for replica path 84).

During signal transmission, primary path 82 of cell 80 may generate (output) an analog radio-frequency signal RFSIG at output terminal 102 based on local oscillator signal LO and data DAT (e.g., performing analog-to-digital conversion and frequency upconversion on data DAT). For example, logic AND gate 90 may generate an output signal by performing a logic AND operation on local oscillator signal LO and data DAT and may drive output capacitor 92 using the output signal. Output capacitor 92 may transmit the output signal onto output terminal 102 as radio-frequency signal RFSIG. Primary path 82 may produce current I (FIG. 4) flowing to the output load of primary path 82.

At the same time, control circuitry in device 10 may use enable signal EN to control replica path 84 to produce a suitable inverse replica current (e.g., replica current I′ of FIG. 4) of the current produced by primary path 82 (e.g., current I of FIG. 1). Enable signal EN may, for example, program replica path 84 to set the magnitude of the replica current to a desired value (e.g., an inverse of the magnitude of the current I consumed by primary path 82). For example, logic AND gate 94 may generate a first output signal by performing a logic AND operation on the data DAT on data path 88 and the enable signal EN received at its second signal input. Inverter 96 may invert the first output signal and may provide the inverted first output signal to the second signal input of logic AND gate 98. Logic AND gate 98 may generate a second output signal by performing a logic AND operation on the local oscillator signal LO on clocking path 86 and the inverted first output signal received from inverter 96. Logic AND gate 98 may drive replica capacitor 100 using the second output signal and a corresponding replica current may be shunted to ground 70 via replica capacitor 100.

Replica path 84 may, for example, be activated or engaged when primary path 82 is deactivated or disengaged but with a matching current profile. Replica capacitor 100 need not have an identical capacitance to output capacitor 92 of primary path 82 but may mimic the load capacitance to ground as seen from the first input terminal of logic AND gate 90 driving output capacitor 92. If desired, replica capacitor 100 may be a tunable (adjustable) capacitor. Replica path 84 may receive a control signal that changes, adjusts, or tunes the capacitance of replica capacitor 100 over time (e.g., to adjust the weight W of current compensation performed by cell 80). The sum of the current consumed by primary path 82 and the replica current produced by replica path 84 may be substantially constant over time, allowing RFDAC 54 to achieve high linearity.

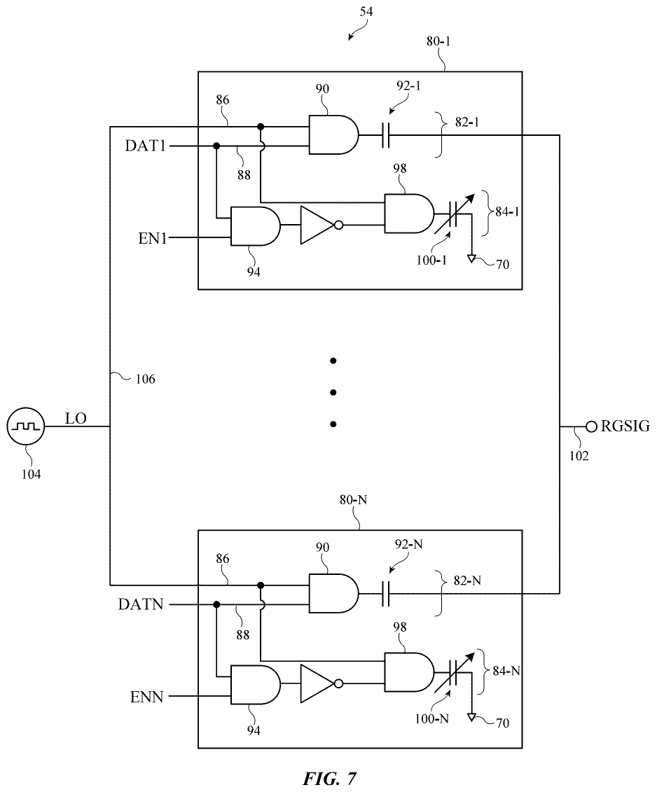

The example of FIG. 6 is illustrative and non-limiting. RFDAC 54 need not utilize a CDAC architecture and may implement other circuit architectures if desired. Primary path 82 and/or replica path 84 may include any desired digital logic gates, drivers, inverters, capacitors, etc., arranged in other manners. FIG. 7 is a circuit diagram showing one example of how RFDAC 54 may include a set of N cells 80.

As shown in FIG. 7, RFDAC 54 may include a set of N cells 80 for generating radio-frequency signal RFSIG at output terminal 102 (e.g., a first cell 80-1, an Nth cell 80-N, etc.). Cells 80 are sometimes also referred to herein as tiles 80. Each cell 80 may include a respective primary path 82 (e.g., cell 80-1 may include a primary path 82-1 having an output capacitor 92-1, cell 80-N may include a primary path 82-N having an output capacitor 92-N, etc.) and a respective replica path 84 (e.g., cell 80-1 may include a replica path 84-1 having a replica capacitor 100-1, cell 80-N may include a replica path 84-N having a replica capacitor 100-N, etc.). In general, N can be 1-10, 10-50, 50-100, 100-1000, more than 1000, or any other integer.

RFDAC 54 may include a clocking path 106 coupled to clocking circuitry 104. Clocking circuitry 104 may include local oscillator circuitry, phase locked loop circuitry, voltage controlled oscillator circuitry, crystal oscillator circuitry, an off-chip oscillator, frequency locked loop circuitry, and/or other types of signal generator for outputting a clock signal, a sinusoidal waveform, or other periodic signal as local oscillator signal LO. Clocking path 106 may route or distribute local oscillator signal LO to the clocking path 86 in the primary path 82 of each of the N cells 80 in RFDAC 54 (e.g., clocking circuitry 104 may be communicatively coupled to N clocking paths 86 over clocking path 106). RFDAC 54 may concurrently transmit and convert N parallel streams or bit positions of data DAT, each provided to a respective cell 80 (e.g., the data path 88 in cell 80-1 may receive data DAT1, the data path 88 in cell 80-N may receive data DATN, etc.). Data DAT1, . . . , DATN are sometimes also referred to herein as data signals DAT1, . . . , DATN. The output of the primary path 82 in each cell 80 may be coupled to output terminal 102. During signal transmission, the signal output by the main path 82 of each cell 80 may collectively form radio-frequency signal RFSIG at output terminal 102. For example, output terminal 102 may form a common output node shared by the N cells 80 of RFDAC 54. At the common output node, local oscillator signal LO may develop a radio-frequency voltage signal (e.g., radio-frequency signal RFSIG) that is proportional to the ratio of activated drivers/capacitors in the primary paths 82 of cells 80 to the total number of cells 80.

The second signal input of the logic AND gate 94 in the replica path 84 of each of the N cells 80 in RFDAC 54 may receive a respective enable signal EN (e.g., cell 80-1 may receive enable signal EN1, cell 80-N may receive enable signal ENN, etc.). Enable signals EN1, . . . , ENN may collectively form the digital code C and/or the digital control signal R (FIGS. 4 and 5) used to control current consumption in RFDAC 54. In general, each enable signal EN may selectively enable or activate the replica capacitor 100 and thus the replica path 84 of its corresponding cell 80. Each of the N output capacitors 92 in cells 80 may have the same size (capacitance) or may have different sizes (capacitances). Each of the N replica capacitors 100 in cells 80 may have the same size (capacitance) or may have different sizes (capacitances). The replica path 84 in each cell 80 may generate a corresponding inverse replica current (e.g., replica current I′ of FIG. 4) of the current consumed by the primary path 82 in that cell 80, producing constant current consumption across RFDAC 54.

When implemented in this way, enable signals EN may serve as a per-cell control signal for enabling/disabling the replica paths 84 across cells 80. This may allow for simple and flexible selection of a limit to the maximum current in replica paths 84. For example, if half of the N replica enable signals EN are set to disable the corresponding replica paths 84 in RFDAC 54, then only half the maximum compensation current is present in the system, effectively scaling limit L. In some implementations, control of enable signals EN may be driven by an already-present LO enablement signal (e.g., a signal that decides the portion of RFDAC 54 that is activated).

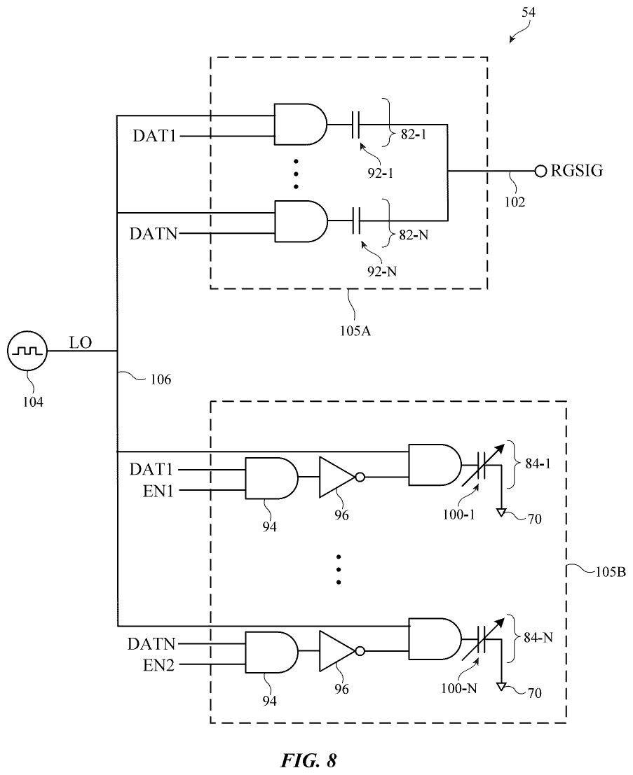

The example of FIG. 7 in which each replica path 84 is co-located or coextensive with the corresponding primary path 82 in an associated cell 80 of RFDAC 54 is illustrative and non-limiting. FIG. 8 shows another example in which the N primary paths 82 of RFDAC 54 are located in a first region (portion) 105A of RFDAC 54 and in which the N replica paths 84 of RFDAC 54 are located in a second region (portion) 105B of RFDAC 54 that is separated from first region 105A. As shown in FIG. 8, each of the N primary paths 82 in region 105A may be coupled in parallel between clocking path 106 and output terminal 102 (e.g., region 105B may collectively form one or more DAC circuits 62 of FIGS. 4 and 5). Each of the N replica paths 84 in region 105B may be coupled in parallel between clocking path 106 and ground 70. The first input signal terminal of the logic AND gate 94 in each of the N replica paths 84 may receive respective data DAT and the second input terminal of the logic AND gate 94 in each of the N replica paths 84 may receive a respective enable signal EN (e.g., replica path 84-1 may receive data DAT1 and enable signal EN1, replica path 84-N may receive data DATN and enable signal ENN, etc.). Separating the main paths and replica paths of RFDAC 54 in this way may, for example, help to simplify enable signal and/or shunt current routing complexity for replica paths 54 relative to the implementation of FIG. 7.

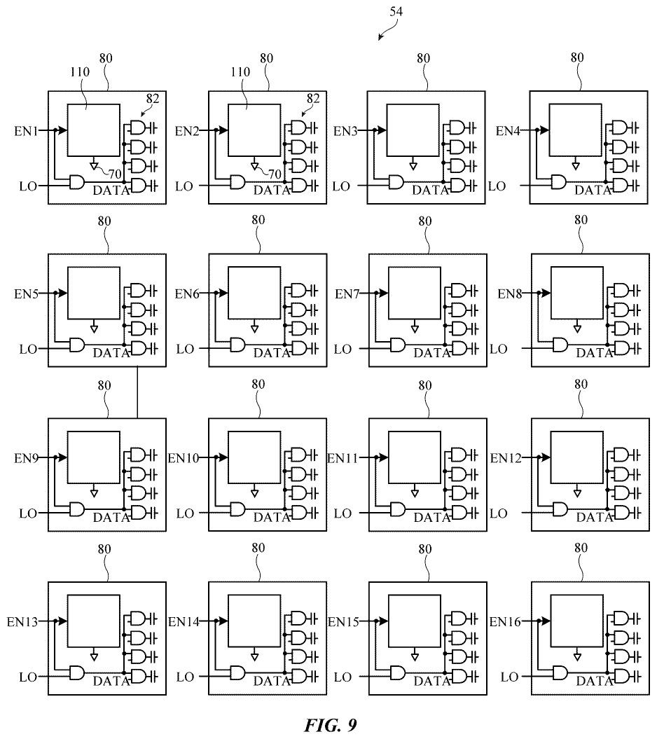

The example of FIG. 8 in which cells 80 are arranged in a single column is illustrative and non-limiting. If desired, as shown in FIG. 9, the N cells 80 of RFDAC 54 may be arranged in an array pattern having multiple rows and columns (e.g., each cell 80 may form a respective tile of the array pattern). In the example of FIG. 9, RFDAC 54 includes N=16 cells 80 arranged in four rows and four columns. Each cell 80 may include a respective current compensation circuit such as compensation circuit 110 and may include one or more primary paths 82. Each compensation circuit 110 may include a corresponding replica path 84 as shown in FIGS. 6 and 7 and may receive a respective enable signal EN (e.g., EN1, EN2, . . . , EN16) that causes the compensation circuit 110 to produce a corresponding inverse replica current shunted to ground 70 (e.g., an inverse replica of the current produced by the primary path 82 of the same cell 80). If desired, the enable signal EN provided to each cell 80 may be shared by the compensation circuit 110 and the primary path(s) 82 of that cell 80 (e.g., using an additional logic AND gate that receives the enable signal and local oscillator signal LO and that drives primary path(s) 82). Implementing RFDAC 54 in this way may, for example, allow the local oscillator signal LO to be shared between cells and compensation circuits.

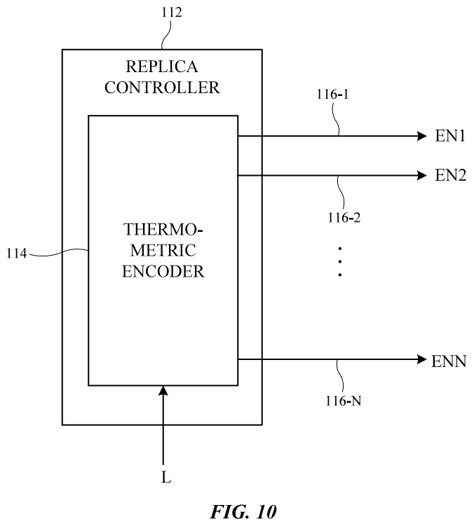

Wireless circuitry 24 (FIG. 3) may include a replica controller (e.g., in processor(s) 26, control circuitry 14 of FIG. 1, etc.) that generates the N enable signals EN that are provided to the N replica paths 84 (e.g., compensation circuits 110 of FIG. 9) in RFDAC 54. FIG. 10 shows one example in which the replica controller includes a thermometric encoder. As shown in FIG. 10, device 10 may include replica circuit controller circuitry such as replica controller 112. Replica controller 112 may generate N enable signals EN1, EN2, . . . , ENN. Each enable signal EN may be provided to a respective replica path 84 (FIGS. 6-9) or compensation circuit 110 (FIG. 9) in RFDAC 54. Each enable signal EN may represent a portion of the digital code C used to control current consumption in RFDAC 54.

If desired, replica controller 112 may include a thermometric controller 112. Thermometric controller 114 may be, for example a 1-to-N thermometric encoder that generates (encodes) N enable signals EN based on a single limit L (e.g., received from other control circuitry in device 10). Each enable signal EN may configure the capacitance of the replica capacitor 100 in the corresponding replica path 54 or compensation circuit 110 to be scaled based on a weight selection (e.g., to provide more or less gain to the replica path or compensation circuit). If desired, the RFDAC may implement a partialisation scheme (e.g., instead of replica capacitor scaling/weighting) when a local replica is implemented by sequentially controlling/enabling different groups of cells (e.g., even and odd numbered cells). In this example, when the replica path in all even cells is enabled while the replica path in all odd cells is disabled, only half the cells are compensated (e.g., with a maximum of half the maximum current consumption). This may adjust the weight value W (FIG. 5) applied to the replica circuit. Note that gain scaling of the compensation circuit may be achieved by shutting on/off the inside of one compensation circuit or multiple correction paths instead of or in addition to capacitance weight scaling. These examples are illustrative and non-limiting. As another example, the shunt circuit and/or the replica controller may be implemented using binary weighted cells or a mixture of thermometric circuitry and binary weighted cells.

If desired, RFDAC 54 may operate on in-phase (i) and quadrature-phase (q) signals (e.g., for transmitting and converting i/q data DAT using an i/q local oscillator signal LO). In these implementations, RFDAC 54 may include respective compensation circuits 110 or replica paths 84 for operating on i signals and q signals. In these implementations, if desired, each cell 80 of RFDAC 54 may switch between operating on i signals and operating on q signals depending on the instantaneous modulation vector (e.g., if more i signal is requested than q signal, more cells may couple to an i local oscillator than a q local oscillator).

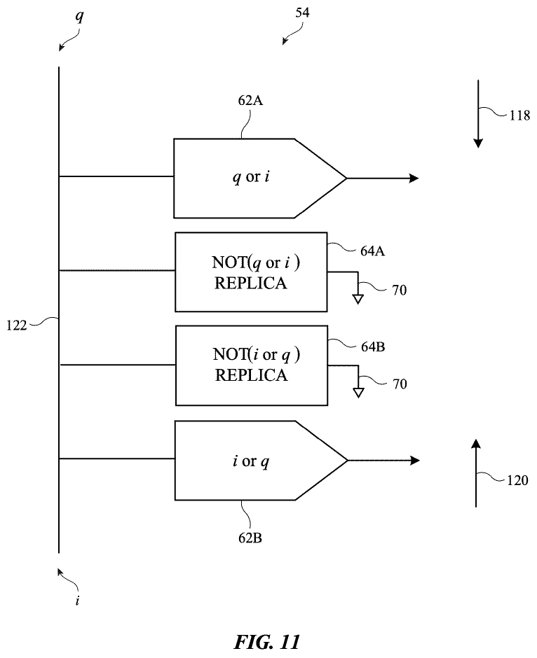

FIG. 11 is a schematic diagram of RFDAC 54 in an implementation where RFDAC 54 operates on i/q signals. As shown in FIG. 11, RFDAC 54 may include a (q or i) DAC circuit 62A having an input coupled to i/q path(s) 122 and having an output coupled to the output terminal 102 of RFDAC 54 (FIGS. 6-8). RFDAC 54 may also include an (i or q) DAC circuit 62B having an input coupled to i/q path(s) 122 and having an output coupled to the output terminal 102 of RFDAC 54. The i/q path(s) 122 may convey q signals (e.g., quadrature-phase data and/or quadrature-phase local oscillator signals) and i signals (e.g., in-phase data and/or in-phase local oscillator signals). DAC circuit 62A may include one or more primary paths 82 (FIGS. 6-9) that operate on (q or i) signals. DAC circuit 62B may include one or more primary paths 82 (FIGS. 6-9) that operate on (i or q) signals.

RFDAC 54 may include a replica circuit 64A coupled to i/q path(s) 122 between DAC circuits 62A and 62B (e.g., for shunting i/q path(s) 122 to ground 70). RFDAC 54 may also include a replica circuit 64B coupled to i/q path(s) 122 between replica circuit 64A and DAC circuit 62B (e.g., for shunting i/q path(s) 122 to ground 70). RFDAC 54 may have a q filling order in the direction of arrow 118 and may have an i filling order in the direction of arrow 120. Replica circuit 64A may include a replica path 84 or compensation circuit 110 (FIGS. 6-9) that operates on (q or i) signals to generate an inverse replica current for DAC 62A. Replica circuit 64B may include a replica path 84 or compensation circuit 110 (FIGS. 6-9) that operates on (i or q) signals and that generates an inverse replica current for DAC 62B. In this context, compared to a single-phase circuit, there may be ambiguity as to what phase each replica circuit 64 operates on (e.g., i or q). If desired, half of the replica circuits may be coupled to the q local oscillator, accepting NOT(i or q), and half the replica circuits may be coupled to the i local oscillator, accepting NOT(q or i) analogous to how shared i/q cells are activated. The indication of i and q in FIG. 11 may be reversed if desired.

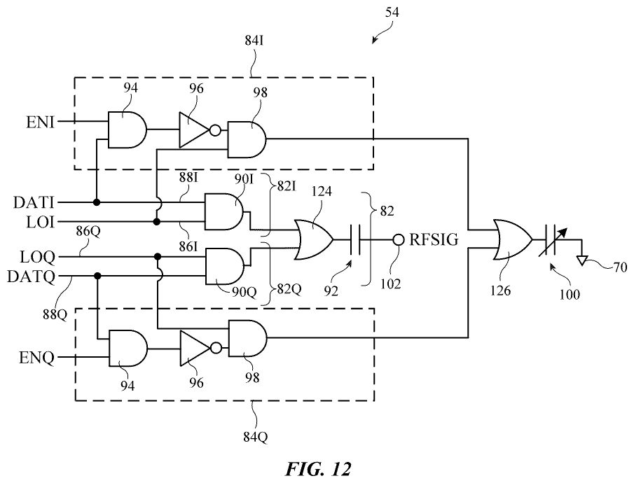

FIG. 12 is a circuit diagram showing one example of circuitry in a cell of RFDAC 54 that operates on i/q signals. As shown in FIG. 12, RFDAC 54 may include an i replica path 84I that operates on i signals and a q replica path 84Q that operates on q signals (e.g., 90 degrees out-of-phase with respect to the i signals). RFDAC 54 may also include replica capacitor 100 and a digital logic OR gate 126 shared by replica paths 84I and 84Q. Replica paths 84I and 84Q may each include respective logic AND gates 94, inverters 96, and logic AND gates 98. Logic OR gate 126 may have a first input communicatively coupled to the output of the logic AND gate 98 in replica path 84I. Logic OR gate 126 may have a second input communicatively coupled to the output of the logic AND gate 98 in replica path 84Q. The output of logic OR gate 126 may be coupled to ground 70 through replica capacitor 100. Replica path 84I, logic OR gate 126, and replica capacitor 100 may collectively form replica circuit 64B of FIG. 11 whereas replica path 84Q, logic OR gate 126, and replica capacitor 100 may collectively form replica circuit 64A of FIG. 11, for example.

RFDAC 54 may include a first primary path 82I that operates on i signals and a second primary path 82Q that operates on q signals. Primary path 82I may include a logic AND gate 90I. The first signal input of logic AND gate 90I may be coupled to i data path 88I. The second signal input of logic AND gate 90I may be coupled to i clocking path 86I. Logic AND gate 90I may receive i data DATI over i data path 88I. Logic AND gate 90I may receive an i local oscillator signal LOI over i clocking path 86I.

Primary path 82Q may include a logic AND gate 90Q. The first signal input of logic AND gate 90Q may be coupled to q data path 88Q. The second signal input of logic AND gate 90Q may be coupled to q clocking path 86Q. Logic AND gate 90Q may receive q data DATQ over q data path 88Q. Logic AND gate 90Q may receive a q local oscillator signal LOQ over q clocking path 86Q. The output of logic AND gate 90Q may be coupled to a first signal input of logic OR gate 124. The output of logic AND gate 90Q may be coupled to a second signal input of logic OR gate 124. The output of logic OR gate 124 may be coupled to output terminal 102 through an output capacitor 92 that is shared by primary paths 82I and 82Q.

During signal transmission, logic AND gate 90I may drive the first signal input of OR gate 124 based on a logic AND operation on i data DATI and i local oscillator signal LOI. At the same time, logic AND gate 90Q may drive the second signal input of OR gate 124 based on a logic AND operation on q data DATQ and q local oscillator signal LOQ. Logic OR gate 124 may perform a logic OR operation on its inputs to drive output capacitor 92 and to produce radio-frequency signal RFSIG on output terminal 102.

The first signal input of the logic AND gate 94 in replica path 84I may receive an i enable signal ENI. The second signal input of the logic AND gate 94 in replica path 84I may be coupled to i data path 88I and may receive i data DATI from i data path 88I. Logic AND gate 94 may drive inverter 96 based on a logic AND operation of i enable signal ENI and i data DATI. Inverter 96 may drive the first signal input of the logic AND gate 98 in replica path 84I using the inverse of the output of logic AND gate 94. At the same time, the second signal input of the logic AND gate 98 in replica path 84I may be coupled to i clocking path 86I and may receive i local oscillator signal LOI from i clocking path 86I. The output of the logic AND gate 98 in replica circuit 84I may drive the first signal input of logic OR gate 126.

At the same time, the first signal input of the logic AND gate 94 in replica path 84Q may receive a q enable signal ENQ. The second signal input of the logic AND gate 94 in replica path 84Q may be coupled to q data path 88Q and may receive q data DATQ from q data path 88Q. Logic AND gate 94 may drive inverter 96 based on a logic AND operation of q enable signal ENQ and q data DATQ. Inverter 96 may drive the first signal input of the logic AND gate 98 in replica path 84Q using the inverse of the output of logic AND gate 94. At the same time, the second signal input of the logic AND gate 98 in replica path 84Q may be coupled to q clocking path 86Q and may receive q local oscillator signal LOQ from q clocking path 86Q. The output of the logic AND gate 98 in replica circuit 84Q may drive the second signal input of logic OR gate 126. Logic OR gate 126 may perform a logic OR operation on the outputs of replica paths 84I and 84Q to drive a replica current to ground 70 through replica capacitor 100 (e.g., where the replica current is an inverse of the current flowing through output terminal 102).

The circuitry shown in FIG. 12 may, for example, represent a single cell 80 of RFDAC 54. In this example, both the i and q paths are preserved, because connecting the replica paths exclusively on the i or q local oscillator would otherwise imbalance the clocking path itself, and the two replica paths may be independently activated (e.g., using the corresponding enable signals). If desired, half of the shared i/q cells in RFDAC 54 may have compensation circuits set to operate on i signals while the other half of the cells may have compensation circuits set to operate on q signals, for example.

If desired, control circuitry 14 may selectively turn on or off the production of an inverse replica current by the replica path(s) 84 in the cell(s) 80 of RFDAC 54 based on the profile of the radio-frequency signal RFSIG to be transmitted by the RFDAC. For example, different power thresholds may be applied to turn replica paths on or off and/or to apply different gains as necessary. This may reduce unnecessary generation of replica current and unnecessary power consumption, such as at lower output powers where the width of current spikes does not otherwise pose a problem to the RFDAC's power supply operation.

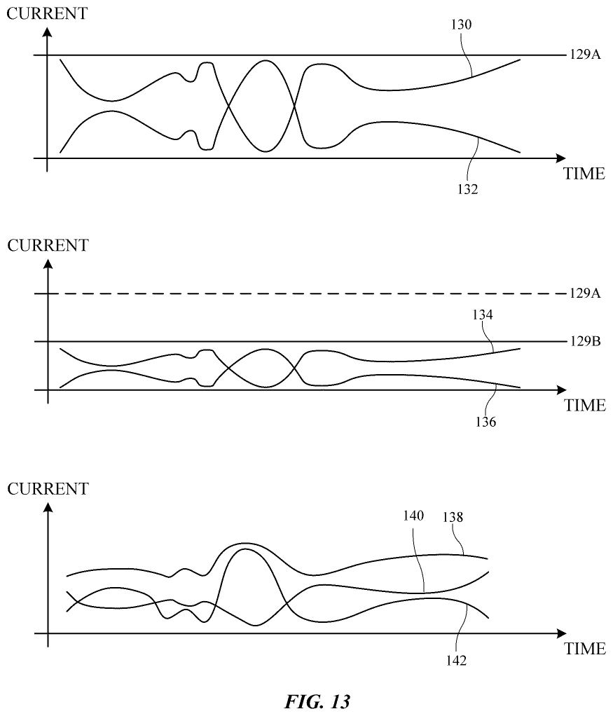

FIG. 13 includes different plots of current as a function of time that illustrate the operation of RFDAC 54. Curve 130 plots the current I consumed/produced by the aggressor circuit (e.g., a primary path 82 of a cell 80 in RFDAC 54) and curve 132 plots the replica current I′ consumed/produced by the corresponding replica path 84 (e.g., shunted to ground 70 through replica capacitor 100) under a first (relatively high) limit L applied to the RFDAC (e.g., depending on the expected peak current of the transmitted signal).

As shown by curves 130 and 132, the replica path may track 100% of the RFDAC current in this example. Note that the replica path 84 (compensation circuit 110) is mostly linear to the applied digital code. However, in practice, some circuits may consume an amount of current that is proportional to, for example, the square of the applied digital code (e.g., with R=L−W₂*C²−W*C², where W and W₂ are applicable weights). The total current consumption may track curve 129A in a first order approximation but, in practice, may be limited (e.g., to a 20 dB reduction of current profile), resulting in a curve 129A that is not entirely linear or flat as shown in FIG. 13.

Curve 134 plots the current I consumed/produced by the aggressor circuit (e.g., a primary path 82 of a cell 80 in RFDAC 54) and curve 136 plots the replica current I′ consumed/produced by the corresponding replica path 84 under a lower limit L applied to the RFDAC (e.g., to accommodate a lower expected peak current). As shown by curves 130 and 132, the replica path may still track 100% of the RFDAC current in this example. Curve 129B shows that total current (e.g., replica current I′ plus current I) through the power supply stays fixed at a constant value that is lower than the curve 129A associated with a higher limit L (e.g., for use when device 10 is operating relatively close to an external antenna). This may, for example, effectively serve as a class-A type implementation of a class-D circuit, completely eliminating the toll of high frequency currents on the supply.

Curves 138-142 plot current consumption when the replica path is programmed/weighted to track 50% of the RFDAC current, using an appropriate limit L (e.g., with weight W=0.5). Curve 140 plots current I and curve 142 plots replica current I′. Curve 138 plots total current (e.g., I+I′) under these conditions. As shown by curve 138, total current consumption is not constant over time. However, the min-to-max current peaks in total current (curve 138) are reduced by 50% relative to the min-to-max current peaks in current I (curve 140) in this example. This may, for example, effectively serve as a class-AB type implementation of a class-D circuit, which may partially compensate for the toll of high frequency currents on the supply. Depending on the situation, the strongest option for optimal current consumption may be completely turning off the compensation circuit or replica path to consume as little current as possible. However, adjusting the RFDAC to perform partial or full compensation when required to optimize performance may serve to alleviate supply-related issues (e.g., with progressively increasing current consumption for progressively increasing radio-frequency performance). Note that in some instances, the option to fully compensate current I using replica current I′ may be dictated by cross-talk concerns, such as when a supply rail is shared with other sensitive circuits, rather than by radio-frequency performance considerations of the RFDAC itself. In addition, it may sometimes be preferable to limit peak-to-peak excursions of the current in the circuit to simplify supply design.

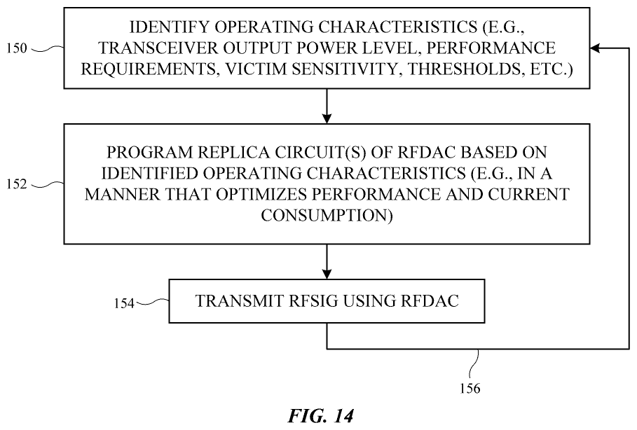

FIG. 14 is a flow chart of illustrative operations involved in transmitting radio-frequency signals RFSIG using RFDAC 54. At operation 150, control circuitry 14 (FIG. 1) may identify one or more operating characteristics of wireless circuitry 24. This may include, for example, a frequency of the radio-frequency signal RFSIG to be transmitted by RFDAC 54, a bandwidth of radio-frequency signal RFSIG, a modulation coding scheme of radio-frequency signal RFSIG, a transceiver output power level, one or more wireless performance requirements (e.g., error vector magnitude (EVM) requirements, adjacent channel leakage ratio (ACLR) requirements, bandwidth targets, etc.), victim sensitivity information (e.g., nearby DCOs, receivers, feedback receiver circuits, etc.), performance thresholds, characteristics about the data or type of data to be carried by radio-frequency signal RFSIG, power requirements or characteristics, and/or any other desired characteristics.

At operation 152, control circuitry 14 may program replica path(s) 84 in RFDAC 54 based on the identified operating characteristic(s). Control circuitry 14 (e.g., replica controller 112 of FIG. 10) may, for example, program, configure, or set one or more of the replica path(s) 84 of one or more cells 80 in RFDAC 54 to be active (e.g., producing a corresponding replica current shunted to ground) or inactive (e.g., without producing replica current) in a manner that optimizes performance and current consumption in RFDAC 54 given the transmission requirements and characteristics of radio-frequency signal RFSIG. If desired, the control circuitry may set weights W (FIG. 5) applied by the replica path(s) and/or limits L (FIG. 10) applied to the replica path(s) while programming the replica path(s). The limit may, for example, be set equal to the maximum current multiplied by a code backoff level, assuming a linear dependency of current verses digital code, weight W may be increased for higher bandwidths of the transmitted signal (e.g., W may be equal to the bandwidth divided by a maximum bandwidth), etc. The programming of the replica path(s) may be performed using look up tables, calculated formulas, and/or other techniques (e.g., taking into account output power level, modulation requirements, victim aggression level, etc.).

At operation 154, RFDAC 54 may generate and transmit radio-frequency signal RFSIG (e.g., while programmed according to operation 152). RFDAC 54 may perform signal domain conversion and frequency upconversion. RFDAC 54 may generate inverse replica current I′ in its replica paths or compensation circuits as programmed at operation 152. RFDAC 54 may exhibit relatively constant current consumption even as the required current profile of the transmitted signal changes over time. RFDAC 54 may transmit radio-frequency signal RFSIG over antenna 42 via amplifier 50 (FIG. 3). Antenna 42 may radiate radio-frequency signal RFSIG. Processing may then loop back to operation 150 via path 156 as the operating characteristic(s) change over time.

The methods and operations described above in connection with FIGS. 1-14 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

As used herein, the term “concurrent” means at least partially overlapping in time. In other words, first and second events are referred to herein as being “concurrent” with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non-simultaneous (e.g., if the first event starts before or after the start of the second event, if the first event ends before or after the end of the second event, or if the first and second events are partially non-overlapping in time). As used herein, the term “while” is synonymous with “concurrent.”

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is merely illustrative and various modifications can be made to the described embodiments. The foregoing embodiments may be implemented individually or in any combination.

What is claimed is:

1. A radio-frequency digital-to-analog converter (RFDAC) comprising:
a signal path;
a set of digital-to-analog converter (DAC) circuits; and
a set of replica circuits, wherein
the RFDAC is configured to receive a digital code,
increasing the digital code increases a number of DAC circuits from the set of DAC circuits that are coupled to the signal path, and
increasing the digital code decreases a number of replica circuits from the set of replica circuits that shunt the signal path to a reference potential.

2. The RFDAC of claim 1, wherein a DAC circuit in the set of DAC circuits comprises:
a first logic AND gate and a first capacitor coupled in series between an output of the first logic AND gate and a radio-frequency output of the RFDAC.

3. The RFDAC of claim 2, wherein a replica circuit in the set of replica circuits comprises:
a replica path coupled between first and second inputs of the first logic AND gate and a ground potential, the replica path including
a second logic AND gate, and
a second capacitor coupled in series between an output of the second logic AND gate and the ground potential.

4. The RFDAC of claim 3, the signal path comprising:
a clocking line coupled to the first input of the first logic AND gate; and
a data line coupled to the second input of the first logic AND gate, wherein
a first input of the second logic AND gate is coupled to the clocking line, and
an output of the second logic AND gate is coupled to the second capacitor.

5. The RFDAC of claim 3, wherein the replica path comprises:
an inverter, wherein a second input of the second logic AND gate is coupled to an output of the inverter; and
a third logic AND gate, wherein an output of the third logic AND gate is coupled to an input of the inverter and a first input of the third logic AND gate is coupled to the data line.

6. The RFDAC of claim 5, wherein a second input of the third logic AND gate is configured to receive an enable signal for the replica path.

7. The RFDAC of claim 6, wherein:
the signal path is configured to produce a signal at the radio-frequency output of the RFDAC, and
the replica path is configured to produce an inverse replica of the signal that is shunted to the ground potential through the second capacitor.

8. The RFDAC of claim 3, wherein the second capacitor is adjustable.

9. The RFDAC of claim 3, further comprising:
a first cell that includes the signal path and the replica path; and
a second cell that includes an additional signal path and an additional replica path, wherein an output of the first cell is communicatively coupled to the radio-frequency output of the RFDAC and an output of the second cell is communicatively coupled to the radio-frequency output of the RFDAC.

10. The RFDAC of claim 9, wherein the second cell comprises:
an additional signal path that includes a third logic AND gate and a third capacitor coupled in series between an output of the third logic AND gate and the output of the second cell; and
an additional replica path coupled between first and second inputs of the third logic AND gate and the ground potential, wherein the additional replica path includes
a fourth logic AND gate, and
a fourth capacitor coupled in series between an output of the fourth logic AND gate and the ground potential.

11. The RFDAC of claim 10, further comprising:
clocking circuitry configured to provide a local oscillator signal to the first input of the first logic AND gate and the first input of the third logic AND gate, wherein the second input of the first logic AND gate is configured to receive a first digital data signal and the second input of the third logic AND gate is configured to receive a second digital data signal.

12. The RFDAC of claim 10, further comprising a two dimensional array of cells that includes the first cell and the second cell.

13. A radio-frequency digital-to-analog converter (RFDAC) comprising:
a signal path;
a set of digital-to-analog converter (DAC) cells; and
a set of replica cells, wherein
the RFDAC is configured to receive a digital code,
a number of DAC cells in the set of DAC cells that are coupled to the signal path is directly proportional to the digital code, and
a number of replica cells from the set of replica cells that shunt the signal path to a reference potential is inversely proportional to the digital code.

14. The RFDAC of claim 13, further comprising:
a first logic OR gate;
a first capacitor coupled between an output of the first logic OR gate and a ground potential;
a second logic OR gate;
a second capacitor coupled between an output of the second logic OR gate and a radio-frequency output of the RFDAC;
a first logic AND gate having an output coupled to a first input of the second logic OR gate;
a second logic AND gate coupled between first and second inputs of the first logic AND gate and a first input of the first logic OR gate;
a third logic AND gate having an output coupled to a second input of the second logic OR gate; and
a fourth logic AND gate coupled between first and second inputs of the third logic AND gate and a second input of the first logic OR gate.

15. The RFDAC of claim 14, further comprising:
a fifth logic AND gate, wherein a first input of the fifth logic AND gate is configured to receive a first enable signal and a second input of the fifth logic AND gate is communicatively coupled to the first input of the first logic AND gate;
a first inverter coupled between an output of the fifth logic AND gate and a first input of the second logic AND gate, wherein a second input of the second logic AND gate is communicatively coupled to the second input of the first logic AND gate;
a sixth logic AND gate, wherein a first input of the sixth logic AND gate is configured to receive a second enable signal and a second input of the sixth logic AND gate is communicatively coupled to the second input of the third logic AND gate; and
a second inverter coupled between an output of the sixth logic AND gate and a first input of the fourth logic AND gate, wherein a second input of the fourth logic AND gate is communicatively coupled to the first input of the third logic AND gate.

16. The RFDAC of claim 15, wherein:
the first enable signal is 90 degrees out of phase with respect to the second enable signal,
the first input of the first logic AND gate and the second input of the fifth logic AND gate are configured to receive a first data signal,
the second input of the first logic AND gate and the second input of the second logic AND gate are configured to receive a first clocking signal,
the second input of the third logic AND gate and the second input of the sixth logic AND gate are configured to receive a second data signal that is 90 degrees out of phase with respect to the first data signal,
the first input of the third logic AND gate and the second input of the fourth logic AND gate are configured to receive a second clocking signal that is 90 degrees out of phase with respect to the first clocking signal,
the second logic OR gate is configured to drive a current onto the radio-frequency output of the RFDAC through the second capacitor, and
the first logic OR gate is configured to produce an inverse replica of the current that is shunted to the ground potential through the first capacitor.

17. Wireless circuitry comprising:
a digital-to-analog converter circuit (DAC) configured to consume a current, wherein the DAC circuit has a first control input configured to receive, from a control path, a digital code that sets an amount of the current consumed by the DAC circuit; and
a replica circuit configured to consume an inverse replica of the current, wherein the replica circuit has a second control input configured to receive a digital control signal that sets an amount of the inverse replica of the current consumed by the replica circuit, the digital control signal comprising some but not all of the digital code.

18. The wireless circuitry of claim 17, further comprising:
an arithmetic circuit coupled between the control path and the second control input of the replica circuit, wherein the arithmetic circuit is configured to subtract the digital code from a constant value.

19. The wireless circuitry of claim 18, further comprising:
a multiplier coupled between the arithmetic circuit and the second control input of the replica circuit, wherein the multiplier is configured to generate the digital control signal by multiplying a signal output by the arithmetic circuit by a weight.

20. The wireless circuitry of claim 19, further comprising:
a power amplifier coupled a radio-frequency output of the DAC circuit; and
an antenna coupled to an output of the power amplifier.
